(19) United States
(12) Patent Application Publication
(10) Pub. No.: US 2006/0071839 A1
(43) Pub. Date: Apr. 6, 2006

(54) Analog-to-digital converter

(76) Inventor: Lung Wen Shieh, Taipei (TW)

Correspondence Address: KUSNER & JAFFE;HIGHLAND PLACE SUITE 310, 6151 WILSON MILLS ROAD, HIGHLAND HEIGHTS, OH, 44143, US

(21) Appl. No.: 10/959,380

(22) Filed: Oct. 6, 2004

(51) Int. Cl. H03M 1/12

(52) U.S. Cl. 341/155

(57) ABSTRACT

The present invention discloses an analog-to-digital converter, which is mainly applied in a digital acoustic signaling system. Conventional AD converter merely has one Schmitt Trigger. Since the bias point is fixed, the change of trigger voltages due to different semiconductor process parameters will cause output digital signals having asymmetric wave pattern. Hence, the transmission quality may deteriorate. The present invention determines the bias point by providing an additional Schmitt trigger. The value of the determined bias would shift with the change of trigger voltages, so the relative variation between them would be eliminated. Therefore, the input analog signals would be correctly converted to the output digital signals.

### FIELD OF THE INVENTION

The present invention is related to an AD (analog-to-digital) converter, especially to a single-terminal AD converter for converting an analog signal to a digital signal.

### BACKGROUND OF THE INVENTION

With the computer becoming the home media center, the popularity of the DVD player, and the widespread application of hi-fi audio amplifier, the demand to the digitization of audio signal has highly raised. There are many advantages of the digital system, such as that the digital system requires less storage space, the computing of the digital system is more accurate than that of the analog system, the digital system is almost unaffected by noise, the signal stored in the digital system is more simple, the signal editing in the digital system is easier, and so on. In order to meet the demand of the consumers, the data have to be transferred rapidly between various digital systems. Hence, an interface standard SPDIF (Sony/Philips Digital Interface Format) is established. In SPDIF, the data can be exchanged in analog signals through coaxial cables, and therefore an AD converter is indispensable.

The conventional converter generally utilizes the comparator, especially the Schmitt Trigger. The Schmitt Trigger is provided with two trigger voltages, which are upper trigger voltage VH and lower trigger voltage VL. When the input is higher than VH, the output voltage would keep at a voltage Va until the input voltage declines to be less than VL. Then, when the input voltage declines to be less than VL, the output voltage would immediately switch to and keep at another voltage Vb until the input voltage rises up to be higher than VH again. Hence, the continuous analog input voltages would be converted to the digital potentials which merely have two states Va and Vb.

FIG. 1 shows the conventional structure of a converter, which is an analog-to-digital converting circuit 10 adopting a Schmitt Trigger. The converting circuit 10 is mainly used to convert the analog signals of input terminal 101 to the digital signals of output terminal 108 by utilizing the Schmitt Trigger 106. The converting circuit 10 may comprise a RC circuit constituted by a resistor 102 and capacitor 103 for providing an impedance match, and a CMOS ESD protection circuit 104 for preventing the damage of electrostatic discharging. The converting circuit 10 may further comprise a pair of resistors 105 for providing a bias point to the Schmitt Trigger 106. Since the resistance is fixed, the bias point is invariable. The converted signal needs to be processed by an inverter 107 before being outputted, because the Schmitt Trigger 106 changes the phase of the signal. In order to obtain a correct corresponding digital signal, the phase of the converted signal should be reversed again.

However, the upper trigger voltage VH and lower trigger voltage VL would drift with the variation of the parameters of the semiconductor process, but the bias point provided by the resistors 105 is fixed. The relative change would let the bias point away from the best position according to the upper and lower trigger points of the Schmitt Trigger, and therefore the waveform of the converted signal becomes unsymmetrical so that the data transmission is influenced and even the converted signal would be incorrect.

In order to solve this problem, the conventional way is proposed by providing two pairs of resistors to determine the optimized bias point. As shown in FIG. 2, another analog-to-digital converting circuit 20 is presented. Besides the original pair of resistors 205, an additional pair of resistors 206 is further provided. Although this structure could overcome the problem of unsuitable position of the bias point, it needs greater gain and consumes much power to be applied in high-speed transmission. Even, more MOS devices are required so that the surface area of such circuit would be enlarged. Since high-speed transmission is an irresistible trend, the converting circuit 20 is fail to provide any effective solution of the aforementioned problem in high-speed transmission. Moreover, with the consideration of cost, the converting circuit 20 is not competent in market, and therefore the converting circuit 20 has significant defect which is also possessed by the converting circuit 10.

### SUMMARY OF THE INVENTION

According the aforementioned problem, the purpose of the present invention provides an AD converter which can eliminate the deviation cased by the drift of the upper and lower trigger point of the Schmitt Trigger. Besides, the AD converter is suitable to be applied in high speed transmission and requires fewer additional MOS devices. The AD converter comprises a first Schmitt Trigger and a second Schmitt Trigger. The first Schmitt Trigger includes a first input terminal and a first output terminal, and the second Schmitt Trigger includes a second input terminal and a second output terminal. The second input terminal is coupled to the first input terminal via a first node, and the second output terminal is coupled to the second input terminal via a second node. A resistor is deposited between the first and second nodes, that is, one end of the resistor is coupled to the first input terminal, and the other end of the resistor is coupled to the second node. The analog signal is inputted to the first Schmitt Trigger through the first input terminal, and the converted digital signal is outputted from the first output terminal of the first Schmitt Trigger.

The present invention also provides an audio signal processing system which is applied to convert an analog audio signal to a digital audio signal and process the digital audio signal. The audio signal processing system comprises an analog audio source for providing the analog input signal. An AD converter is used to convert the analog input signal to the digital output signal, and includes a first Schmitt Trigger and a second Schmitt Trigger. A resistor is deposited between the first and second Schmitt Triggers, and a digital audio device is coupled to the output terminal of the converter for receiving the digital output signal. The digital audio device may be a personal computer, a laptop computer, an audio amplifier, a DVD player, a VCD player, or a MP3 player. The second Schmitt Trigger is applied to adjust the bias point for the first Schmitt Trigger.

### BRIEF DESCRIPTION OF THE DRAWINGS

FIG. 1 shows a conventional AD converter.

FIG. 2 shows another conventional AD converter.

FIG. 3 shows an AD converter according to the present invention.

FIG. 4 is a table showing the simulation results of the AD converter according to the present invention.

FIG. 5 shows an audio signal processing system according the present invention.

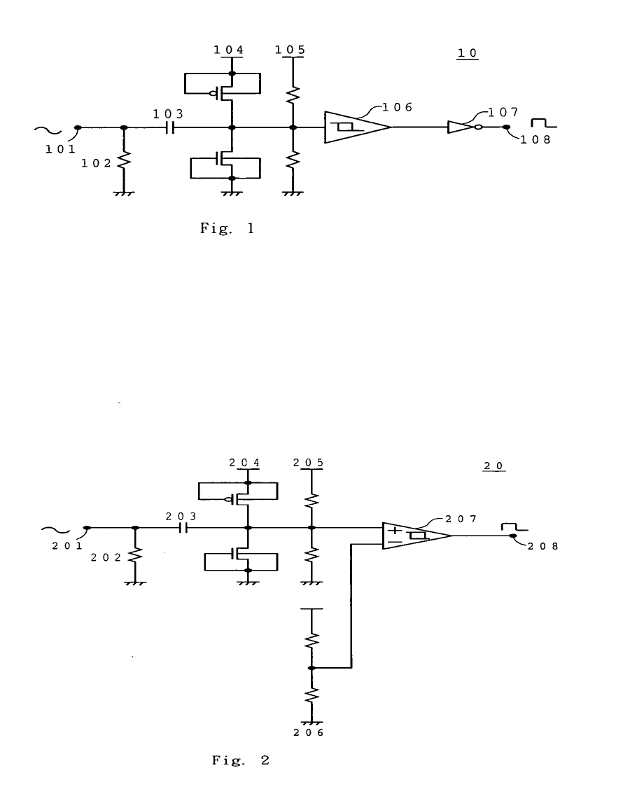

### DETAILED DESCRIPTION OF THE PREFERRED EMBODIMENT

The AD converter of the present invention is described with the preferred embodiments and accompanying drawings. It should be appreciated that all the preferred embodiments are merely used for illustration. Hence, the present invention can also be applied to various embodiments other than the preferred embodiments. Besides, the present invention is not limited to any embodiment but to the appending claims and their equivalents.

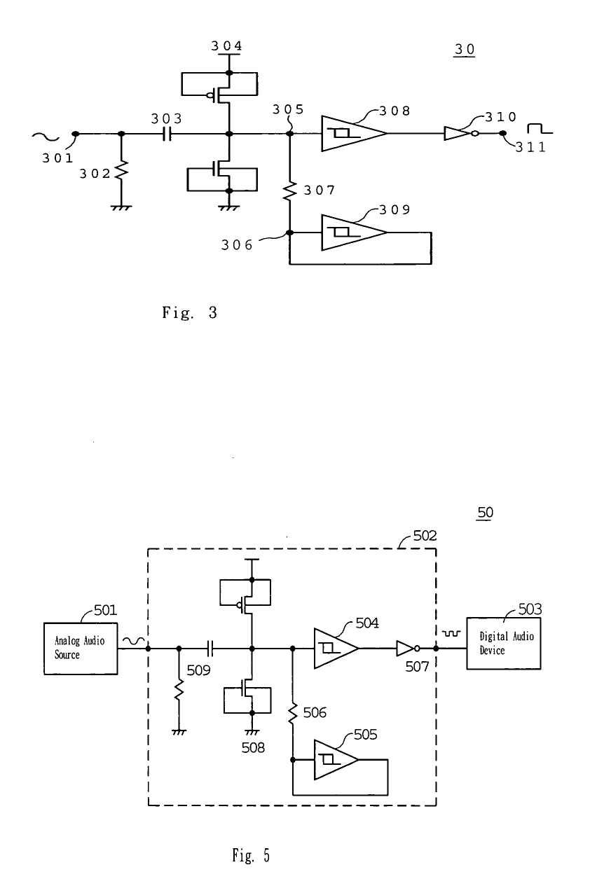

A preferred embodiment of the present invention is shown in FIG. 3. In this embodiment, an AD converter 30 is able to convert an analog signal from an input terminal 301 to a digital signal of an output terminal 311. The AD converter may comprise a RC circuit constituted by a resistor 302 and a capacitor 303 for providing the input impedance to prevent the signal reflection in the input terminal 301. Additionally, in one embodiment of the present invention, the AD converter may further couple to an ESD protection circuit 304. To prevent the damage caused by the electrostatic discharging, the ESD protection circuit 304 might adopt the COMS ESD protection circuit or the protection circuit constituted by a diode as knows in the art.

The AD converter of the embodiment comprises two Schmitt Triggers 308 and 309. The first Schmitt Trigger 308 is mainly used to convert the analog signal of the input terminal 301 to the digital signal of the output terminal 311, and the second Schmitt Trigger 309 is applied to determine the position of the bias point V_{bias}. Between the first and second Schmitt Triggers 308 and 309, a resistor 307 may be deposited to separate them. According to one embodiment of the present invention, the resistance of the resistor 307 may be about 10K ohm, and it should be appreciated that such value is merely recited for illustration instead of limitation. Any suitable value of resistance can be adopted in the present invention. The resistor 307 is mainly used to provide an impedance isolation or separation between the first and second Schmitt Triggers 308 and 309. The first Schmitt Trigger includes a first input terminal and a first output terminal, and the second Schmitt Trigger includes a second input terminal and a second output terminal. The second input terminal and second output terminal are both coupled to a node 306, and one end of the resistor 307 is coupled to the node 306, too. The other end of the resistor 307 is coupled to a node 305. In other words, the resistor 307 is deposited between the first input terminal and the second input terminal. The signal inputted through the input terminal 301 is led to the first Schmitt Trigger 308 via the node 305, and the resistor 307 is coupled to the first Schmitt Trigger 308 via the node 305, too. The first input terminal of the first Schmitt Trigger 308 may be coupled to an inverter 310, and the output terminal of this inverter 310 is the output terminal 311 of the AD converter 30.

A feedback circuit for compensation is formed by the connection of the second Schmitt Trigger 309 according to above embodiment. A direct voltage is then generated and becomes the greatest gain of the first Schmitt Trigger 308. This direct voltage would be provided for the first Schmitt Trigger 308 to adjust the bias point V_{bias}. Although the upper and lower trigger points VH and VL would drift with the changing of the semiconductor process parameters, the outputted direct voltage of second Schmitt Trigger 309 would relatively deviate to compensate the drift. Therefore, the absolute level difference between the upper and lower trigger pints is almost invariable. Besides, the first Schmitt Trigger 308 operates at the highest point of the gain, so fewer MOS devices would be used in high-speed transmission. Thus, not only the power consuming is reduced, but also the production cost is decreased.

Since the Schmitt Trigger would alter the phase of the signal, the inverter 310 is provided in the first output terminal of the first Schmitt Trigger 308 for reversing the phase again to obtain the correct corresponding digital signal. Moreover, in above embodiments, the coupling between components may be electrical connection or physical connection.

It should be appreciated that the input and output terminals of the AD converter 30 in this embodiment may respectively couple to other devices or components, such as the RC circuit, the CMOS ESD protection circuit 304, and the inverter 310. The aforementioned additional components are not the essential elements of the AD converter 30, and could be replaced by any device with similar functions. The foregoing formations are merely described for illustration instead of limitation.

The simulation result of one embodiment of the present invention is shown in a table of FIG. 4. In FIG. 4, V_{bias} represents the bias point provided by the second Schmitt Trigger 309, VH and VL respectively represent the upper and lower trigger pints of the first Schmitt Trigger 308, and VH−VL represents the level difference between of the upper and lower trigger points. The unit of the above voltages is volt. Besides, NMOS and PMOS are the parameters of the semiconductor process and the TEMP is the outside temperature in Centigrade (° C.) while the converter is operating, that is, the temperature of operation environment. As we can see in the table of FIG. 4, although the levels of the upper and lower trigger points of the first Schmitt Trigger 308 drift with the variation of semiconductor process parameters and operation temperature, i.e. the values of PMOS, NMOS, and TEMP, the bias point Vbias determined by the second Schmitt Trigger 309 would automatically adjust, too. Therefore, the level difference between the upper and lower trigger points remains almost the same, and the negligible changes are within the tolerable range. Hence, the present invention can solve the drift problem caused by the variation of semiconductor process parameters. It should be appreciated that the aforementioned parameters and values are cited for illustration instead of limitation. Other semiconductor process parameters or voltages can be appropriately used in various embodiments of the present invention.

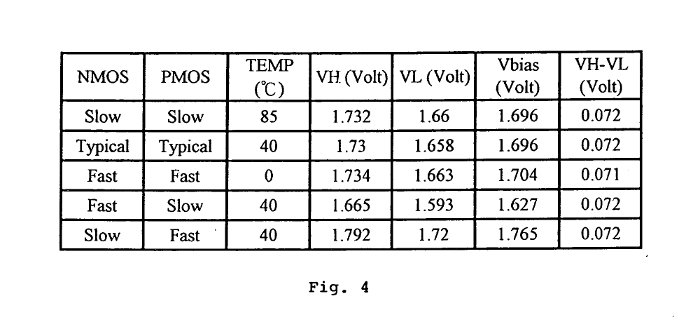

According to another embodiment of the present invention, an audio signal processing system 50 comprising an analog audio source 501, an AD converter 502, and a digital audio device 503 is shown in FIG. 5. The analog audio source 501 provides various analog signals, and may include the computer or audio/video player with SPDIF interface. All the audio signals in the digital audio device 503 are digital signals, and the audio device 503 is capable of processing the digital signal, such as storing, transmission, copying, modification, editing, adding echoes, combing, and so on. In this embodiment, the digital audio device 503 may includes the audio amplifier, the DVD player, the VCD player, or MP3 player.

Since the audio signal source 501 of the audio signal processing system 50 provides analog signals, the AD converter 502 is required to allow the digital audio device 503 receiving and processing the data from the analog audio source 501. In this embodiment, the AD converter 502 has two Schmitt Triggers, which are the first Schmitt Trigger 504 and the second Schmitt Trigger 505, and a resistor 506 is deposited between them for impedance separation. The first Schmitt Trigger 504 has upper and lower trigger points VH and VL for converting the analog signal to the digital signal. As shown in FIG. 5, the output terminal (second output terminal) and the input terminal (second input terminal) of the second Schmitt Trigger 505 are coupled to each other and to one end of the resistor 506, and the other end of the resistor 506 is coupled to the input terminal (first input terminal) of the first Schmitt Trigger 506. In other words, the resistor 506 is deposited between the first and the second input terminals, and a feedback circuit for compensation is formed by the second Schmitt Trigger 505 to provide a direct voltage. This direct voltage may be used as the bias point V_{bias} of the first Schmitt Trigger 504.

Although the upper and the lower trigger points VH and VL of the first Schmitt Trigger 504 would drift with the changing of the semiconductor process parameters, the outputted direct voltage of second Schmitt Trigger 309 would relatively deviate to compensate the drift. Therefore, the absolute difference between the levels of VH and VL remains almost the same, and the simulation result could refer to the table of FIG. 4.

Moreover, since the Schmitt Trigger would change the phase of the signal, the outputted signal may be processed by the inverter 507 to alter the phase again to obtain the correct corresponding signal. The coupling of the above elements within the audio signal processing system 50 may be electrical connection or physical connection.

Other than the foregoing elements, the AD converter 502 may further comprise the RC circuit 509 constituted by a resistor and a capacitor. The RC circuit 509 is used to provide the input impedance match for preventing the signal reflection in the input terminal. In order to avoid the damage of electrostatic discharging, the AD converter 503 may further comprise an ESD protection circuit 508, and the ESD protection circuit 304 could adopt COMS ESD protection circuit or the protection circuit constituted by the diode. The RC circuit 509, the ESD protection circuit 508, and the inverter 507 are not essential in the analog-to-digital converter. They could be replaced by other functional equivalents, and such modifications should be included in the present invention.

The digital audio signals converted by the AD converter 502 will be transferred to the digital audio device 503 for various processing.

A feedback circuit for compensation is formed by the connection of the second Schmitt Trigger 505 according to above embodiment. A direct voltage is then provided and becomes the greatest value of the gain of the first Schmitt Trigger 504. This direct voltage would be provided for the first Schmitt Trigger 504 to adjust the bias point V_{bias}. Although the upper and lower trigger point VH and VL would drift with the changing of the semiconductor process parameters, the outputted direct voltage of second Schmitt Trigger 505 would relatively deviate to compensate the drift. Therefore, the absolute difference between the levels of upper and lower trigger pints remain almost the same. Besides, the first Schmitt Trigger 504 operates at the greatest point of the gain, so fewer MOS devices would be used in high-speed transmission. Thus, not only the power consuming is reduced, but also the production cost is decreased.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

We claim:

1. An analog-to-digital converter comprising:
a first Schmitt Trigger including a first input terminal and a first output terminal;
a second Schmitt Trigger including a second input terminal and a second output terminal, wherein said second input terminal is coupled to said first input terminal via a first node, and said second output terminal is coupled to said second input terminal via a second node; and
a resistor coupled to said first node and said second node;
wherein an analog signal is inputted to said first Schmitt Trigger through said first input terminal, and a converted signal is outputted from said first Schmitt Trigger through said first output terminal.

2. The analog-to-digital converter as set forth in claim 1, wherein said second Schmitt Trigger is used to adjust a bias point for said first Schmitt Trigger.

3. The analog-to-digital converter as set forth in claim 1, wherein an ESD (electrostatic discharge) protector is coupled to said analog-to-digital converter for avoiding the damage of electrostatic discharging.

4. The analog-to-digital converter as set forth in claim 3, wherein said ESD protector includes a CMOS ESD protection circuit.

5. The analog-to-digital converter as set forth in claim 1, wherein a RC circuit is coupled to said analog-to-digital converter for providing input impedance.

6. The analog-to-digital converter as set forth in claim 1, wherein the resistance of said resistor is about 10,000 ohm.

7. The analog-to-digital converter as set forth in claim 1, wherein an inverter is coupled to said first output terminal for reversing the phase of said converted signal.

8. An audio signal processing system, which comprises:
an analog audio source for providing an analog input signal;
an AD (analog-to-digital) converter coupled to said analog audio source for converting said analog input signal to a digital output signal, wherein said AD converter includes a first Schmitt Trigger and a second Schmitt Trigger, and a resistor is deposited between said first and second Schmitt Triggers; and
a digital audio device coupled to said AD converter for receiving said digital output signal;
wherein said second Schmitt Trigger is used to adjust a bias point for said first Schmitt Trigger.

9. The audio processing system as set forth in claim 8, wherein said second Schmitt Trigger includes a second input terminal and a second output terminal, and said second input and output terminals are both coupled to a node, wherein said node is coupled to one end of said resistor, and the other end of said resistor is coupled to a first input terminal of said first Schmitt Trigger.

10. The audio processing system as set forth in claim 8, wherein an ESD (electrostatic discharge) protector is coupled to said AD converter for avoiding the damage of electrostatic discharging.

11. The audio processing system as set forth in claim 10, wherein said ESD protector includes a CMOS ESD protection circuit.

12. The audio processing system as set forth in claim 8, wherein a RC circuit is coupled to said AD converter for providing input impedance.

13. The audio processing system as set forth in claim 8, wherein the resistance of said resistor is about 10,000 ohm.

14. The audio processing system as set forth in claim 8, wherein said digital audio device includes a computer.

15. The audio processing system as set forth in claim 8, wherein said digital audio device includes an audio/video player.

16. The audio processing system as set forth in claim 15, wherein said audio/video player includes an audio amplifier, DVD player, VCD player, or a MP3 player.

17. The audio processing system as set forth in claim 8, wherein an input end of an inverter is coupled to an output terminal of said first Schmitt Trigger, and an output end of said inverter is coupled to said digital audio device.
